(19) United States
(12) Patent Application Publication
(10) Pub. No.: US 2025/0316640 A1
(43) Pub. Date: Oct. 9, 2025

(54) SEMICONDUCTOR PACKAGE

(71) Applicant: Samsung Electronics Co., Ltd., Suwon-si (KR)

(72) Inventors: Wonil SEO, Suwon-si (KR); Taeduk NAM, Suwon-si (KR); Hogeon SONG, Suwon-si (KR); Jiwon SHIN, Suwon-si (KR); Kwangyong LEE, Suwon-si (KR)

(73) Assignee: Samsung Electronics Co., Ltd., Suwon-si (KR)

(21) Appl. No.: 18/950,350

(22) Filed: Nov. 18, 2024

(30) Foreign Application Priority Data
Apr. 4, 2024 (KR) 10-2024-0045744

(51) Int. Cl. H01L 23/00; H01L 23/31; H01L 23/498; H01L 25/065

(52) U.S. Cl. CPC H01L 24/48; H01L 23/49816; H01L 23/49838; H01L 24/08; H01L 24/45; H01L 24/49; H01L 24/73; H01L 25/0657; H01L 23/3135; H01L 24/32; H01L 2224/08111; H01L 2224/32145; H01L 2224/32225; H01L 2224/45139; H01L 2224/45144; H01L 2224/45147; H01L 2224/48105; H01L 2224/48111; H01L 2224/48148; H01L 2224/48228; H01L 2224/49109; H01L 2224/73265; H01L 2225/06506; H01L 2225/0651; H01L 2225/06562; H01L 2225/06593; H01L 2924/152

(57) ABSTRACT

A semiconductor package includes a package substrate including an insulating layer, an interconnection circuit, and upper pads and lower pads electrically connected through the interconnection circuit, a plurality of semiconductor chips stacked including connection pads, a support structure contacting a side surface of a first semiconductor chip, which is an uppermost one among the plurality of semiconductor chips and at least a portion of an upper surface of a second semiconductor chip, which is one among the plurality of semiconductor chips below the first semiconductor chip, a first connection structure connecting the upper pads of the package substrate to the connection pads of the second semiconductor chip, a second connection structure connecting the connection pads of the first semiconductor chip to the connection pads of the second semiconductor chip, and an encapsulant covering the plurality of semiconductor chips, the first connection structure, and the second connection structure.

### CROSS-REFERENCE TO RELATED APPLICATION(S)

This application claims benefit of priority to Korean Patent Application No. 10-2024-0045744 filed on Apr. 4, 2024 in the Korean Intellectual Property Office, the disclosure of which is incorporated herein by reference in its entirety.

### BACKGROUND

The present inventive concepts relate to semiconductor packages.

Recently, there has been demand for high performance and high capacity in semiconductor packages installed in electronic devices. Accordingly, semiconductor packages including a plurality of semiconductor chips and control chips controlling operations of the plurality of semiconductor chips have been developed, and research has been conducted to reduce the size of the packages to embed a greater number of chips.

### SUMMARY

Some example embodiments of the present inventive concepts provide lightweight and thin semiconductor packages.

According to an example embodiment of the present inventive concept, a semiconductor package includes a package substrate including an insulating layer, an interconnection circuit, upper pads and lower pads, the interconnection circuit being in the insulating layer and connecting the upper pads and the lower pads, a plurality of semiconductor chips stacked in a direction perpendicular to an upper surface of the package substrate, each of the plurality of semiconductor chips including connection pads spaced apart from each other in a first direction on one side of an upper surface thereof, a support structure contacting at least a portion of a side surface of a first semiconductor chip and at least a portion of an upper surface of a second semiconductor chip, the first semiconductor chip being an uppermost one among the plurality of semiconductor chips, the second semiconductor chip being one among the plurality of semiconductor chips below the first semiconductor chip, a first connection structure extending in a second direction intersecting the first direction, the first connection structure connecting the upper pads of the package substrate to the connection pads of the second semiconductor chip, the connection pads of the second semiconductor chip being adjacent to the upper pads of the semiconductor package in the second direction, a second connection structure extending along the upper surface of the first semiconductor chip, a side surface of the support structure, and the upper surface of the second semiconductor chip and connecting the connection pads of the first semiconductor chip to the connection pads of the second semiconductor chip, the connection pads of the second semiconductor chip being adjacent to the connection pads of the first semiconductor chip in the second direction, and an encapsulant covering at least a portion of each of the plurality of semiconductor chips, the first connection structure, and the second connection structure, wherein the support structure has an inclined side surface having a width increasing toward the upper surface of the second semiconductor chip.

According to an example embodiment of the present inventive concept, a semiconductor package includes a package substrate including upper pads and lower pads, a plurality of semiconductor chips sequentially stacked on the package substrate, each of the plurality of semiconductor chips including connection pads arranged on a first side surface portions thereof in a first direction, a support structure being adjacent to a first side surface of at least one semiconductor chip among the plurality of semiconductor chips, a first connection structure electrically connecting one of the upper pads to one of the connection pads, and a second connection structure electrically connecting the connection pads of at least one pair of vertically adjacent semiconductor chips among the plurality of semiconductor chips, with each other, wherein the second connection structure includes a barrier layer and a conductive layer on the barrier layer, the barrier layer being in contact with a corresponding pair of the connection pads of the at least one pair of vertically adjacent semiconductor chips, and the first connection structure is in contact with an upper surface of the conductive layer.

According to an example embodiment of the present inventive concept, a semiconductor package includes a package substrate including upper pads aligned in a first direction, a plurality of semiconductor chips stacked on the package substrate in a vertical direction, the plurality of semiconductor chips including connection pads aligned in the first direction on one side of an upper surface thereof, a support structure being between the connection pads of each of at least one pair of adjacent semiconductor chips among the plurality of semiconductor chips, in plan view, a bonding wire electrically connecting one of the upper pads to a corresponding one of the connection pads, and a plurality of conductive lines electrically connecting the connection pads of the at least one pair of semiconductor chips, with each other, wherein the plurality of conductive lines intersect the support structure in plan view.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a plan view of a semiconductor package according to an example embodiment of the present inventive concepts, and FIG. 1B is a cross-sectional view illustrating the semiconductor package of FIG. 1A taken along line I-I′;

FIG. 2 is a cross-sectional view of a semiconductor package according to an example embodiment of the present inventive concepts;

FIG. 3 is a cross-sectional view of a semiconductor package according to an example embodiment of the present inventive concepts;

FIG. 4A is a plan view of a semiconductor package according to an example embodiment of the present inventive concepts, and FIG. 4B is a cross-sectional view of the semiconductor package of FIG. 4A taken along line I-I′; and

FIGS. 5A to 9B are plan views and cross-sectional views schematically illustrating a manufacturing process of a semiconductor package according to an example embodiment of the present inventive concepts.

### DETAILED DESCRIPTION

Hereinafter, some example embodiments of the present inventive concepts are described with reference to the accompanying drawings. Unless otherwise specified, in this specification, terms, such as ‘top,’ ‘upper surface, ‘bottom,’ ‘lower surface, ‘side surface,’ etc. are based on the drawings and may vary depending on directions in which components are actually arranged.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

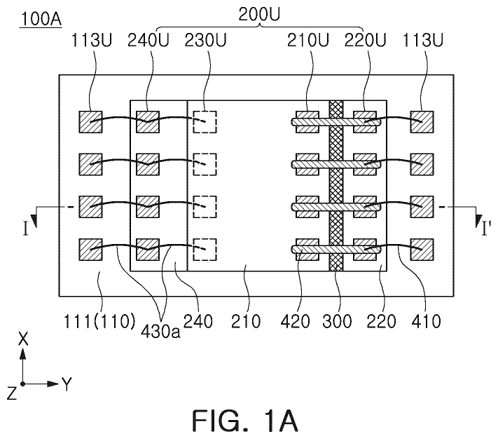

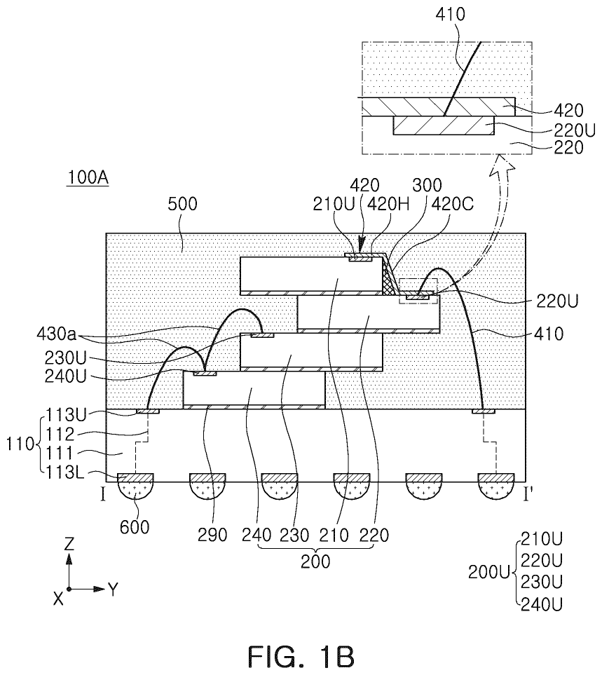

FIG. 1A is a plan view of a semiconductor package according to an example embodiment of the present inventive concepts, and FIG. 1B is a cross-sectional view of the semiconductor package of FIG. 1A taken along line I-I′.

Referring to FIGS. 1A and 1B, a semiconductor package 100A of an example embodiment may include a package substrate 110, a plurality of semiconductor chips 200, a support structure 300, a first connection structure 410, a second connection structure 420, and an encapsulant 500. Referring to FIGS. 1A and 1B, the semiconductor package 100A of an example embodiment may further include external connection conductors 600.

The package substrate 110 may include an insulating layer 111 and an interconnection circuit 112. The package substrate 110 may further include a via structure electrically connecting the interconnection circuits 112 located on different levels. The package substrate 110 may be a semiconductor package substrate including a printed circuit board (PCB), a ceramic substrate, a glass substrate, or a tape wiring substrate.

The insulating layer 111 may include an insulating resin. The insulating resin may include a thermosetting resin, such as an epoxy resin, a thermoplastic resin, such as polyimide, or a resin impregnated with an inorganic filler or/and glass fiber (glass cloth, glass fabric, etc.), such as prepreg, Ajinomoto build-up film (ABF), FR-4, and bismaleimide triazine (BT). The insulating resin may include a photosensitive resin, such as photoimageable dielectric (PID) resin. For example, when the package substrate 110 is a PCB, the insulating layer 111 may be a core insulating layer (e.g., prepreg) of a copper clad laminate. The insulating layer 111 may have a large number of insulating layers stacked in a vertical direction (e.g., a Z-axis direction), and depending on the process, the boundaries between the first insulating layers on different levels may not be apparent.

The interconnection circuit 112 is disposed within the insulating layer 111 and may form an electrical path within the package substrate 110. The interconnection circuit 112 may include at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), or an alloy including two or more metals thereof. The interconnection circuit 112 may be a plurality of interconnection circuits 112 located on different levels between the plurality of insulating layers 111.

Upper pads 113U may be disposed on an upper surface of the insulating layer 111, and lower pads 113L may be disposed on a lower surface of the insulating layer 111. The upper pads 113U and lower pads 113L may be electrically connected through the interconnection circuit 112. The upper pads 113U may be electrically connected to the plurality of semiconductor chips 200 through connection structures on the insulating layer 111, and the lower pads 113L may be electrically connected to the plurality of external connection conductors 600 below the insulating layer 111. The upper pads 113U and the lower pads 113L may include the same material as the interconnection circuit, but are not limited thereto. In an example embodiment, the upper pads 113U may include at least one metal selected from copper (Cu), nickel (Ni), and gold (Au), or an alloy including two or more metals thereof, but is not limited thereto.

The plurality of semiconductor chips 200 may include, but are not limited to, a plurality of semiconductor chips 200 stacked in a direction, perpendicular to the upper surface of the package substrate 110, and a greater number of semiconductor chips than those illustrated in the drawing may be provided. The plurality of semiconductor chips 200 may overlap each other in a direction (e.g., a Z-axis direction), perpendicular to the upper surface of the package substrate 110. The plurality of semiconductor chips 200 may be stacked offset in a second direction (e.g., a Y-axis direction) so as to be adjacent to one side, but are not limited thereto. The plurality of semiconductor chips 200 may be stacked, having the side surfaces of the plurality of semiconductor chips are offset aligned not to match each other. In an example embodiment, the plurality of semiconductor chips 200 may not be aligned side by side in the second direction but may be arranged in a zigzag shape. The plurality of semiconductor chips 200 may be arranged in a staircase shape with a portion of an upper surface thereof exposed from other semiconductor chips. In an example embodiment, some of the semiconductor chips 200 may be arranged to overlap in the vertical direction.

Among the plurality of semiconductor chips, the bottommost semiconductor chip 240 may be a bare integrated circuit (IC) without separate bumps or interconnection layers, but without being limited thereto. The bottommost semiconductor chip 240 may be a packaged-type IC. The IC may be a processor chip, such as a central processing unit (CPU), a graphics processing unit (GPU), a field programmable gate array (FPGA), an application processor (AP), a digital signal processor, a cryptographic processor, a microprocessor, or a microcontroller. However, without being limited thereto, the IC may be a logic chip, such as an analog-to-digital converter or an application-specific IC (ASIC), or a memory chip including a volatile memory, such as dynamic RAM (DRAM) and static RAM (SRAM), on including a nonvolatile memory, such as a phase change RAM (PRAM), a magnetic RAM (MRAM), a resistive RAM (RRAM), a flash memory, etc. The semiconductor chips 210, 220, and 230 stacked on a bottommost semiconductor chip 240 may have the same or similar characteristics as those of the bottom semiconductor chip 240.

The plurality of semiconductor chips 200 are arranged adjacent to one side on an upper surface thereof and may include connection pads 200U spaced apart from each other in the first direction (e.g., the X-axis direction). The connection pad 200U may include a conductive material, and in an example embodiment, the connection pad 200U may include aluminum (Al), but is not limited thereto. The connection pads 200U may be electrically connected to an internal circuit of the semiconductor chip 200 and may transmit an electrical signal from the internal circuit. The connection pads 200U may be aligned and arranged on one side from which the upper surface of each of the plurality of semiconductor chips 200 is exposed.

The plurality of semiconductor chips 200 may be attached to each other by an adhesive film 290 (e.g., DAF), and the bottommost semiconductor chip 240 may be attached to the upper surface of the package substrate 110 by the adhesive film 290.

The support structure 300 may be disposed to contact at least a portion of each of the side surface of the first semiconductor chip 210 and the upper surface of the second semiconductor chip 220 among the plurality of semiconductor chips 200. The support structure 300 may cover at least a portion of the side surface of the first semiconductor chip 210 and may have an inclined shape widening toward the upper surface of the second semiconductor chip 220, but is not limited thereto. One side surface of the support structure 300 may be in contact with at least a portion of the side surface of the first semiconductor chip 210 and may extend in the first direction (e.g., the X-axis direction) to be parallel to the side surface of the first semiconductor chip 210. Another side surface of the support structure 300 may contact at least a portion of the second connection structure 420.

The support structure 300 may include a known insulating resin, such as an epoxy resin. The support structure 300 may cover at least a portion of one side surface of the first semiconductor chip 210 and may serve to physically and electrically protect a conductive pattern disposed outside the first semiconductor chip 210 to mitigate or prevent the conductive pattern from being damaged by the second connection structure 420 formed on the support structure 300.

The first connection structure 410 may electrically connect some of the plurality of semiconductor chips 200 to the package substrate 110. For example, the first connection structure 410 may contact each of the connection pads 220U disposed on the upper surface of the second semiconductor chip 220 and electrically connect the connection pads 220U to the upper pads 113U. The first connection structure 410 may directly contact the connection pad 220U, and the second connection structure 420 disposed on the connection pad 220U may have a structure surrounding at least a portion of the first connection structure 410. However, without being limited thereto, and according to an example embodiment, the first connection structure 410 may have a structure contacting the upper surface of the second connection structure 420. The first connection structure 410 may include a conductive material. For example, the first connection structure 410 may be formed of gold (Au), silver (Ag), copper (Cu), or alloys thereof, but is not limited thereto. The first connection structure 410 may be referred to as a bonding wire.

The second connection structure 420 may be disposed on a portion of the upper surface of the plurality of semiconductor chips 200 and the support structure 300, respectively. The second connection structure 420 may contact at least a portion of the side surface of the support structure 300. When the support structure 300 has an inclined side surface, the second connection structure 420 may extend along the inclined side surface of the support structure 300, but is not limited thereto. The second connection structure 420 may have different morphological characteristics depending on the shape of the support structure 300. The second connection structure 420 may extend in the second direction (e.g., the Y-axis direction), which intersects the first direction (e.g., the X-axis direction), and contact the connection pads 200U located on different levels. For example, the second connection structure 420 may contact the connection pads 210U disposed on the upper surface of the first semiconductor chip 210 and the connection pads 220U disposed on the upper surface of the second semiconductor chip 220 and provides electrical connection therebetween. A width of the second connection structure 420 in the first direction may be less than a width of each of the connection pads 200U in the first direction, but is not limited thereto. The second connection structure 420 may be in contact with the center of the connection pads 200U, but is not limited thereto. According to an example embodiment, the second connection structure 420 may overlap the outer periphery of the connection pads 200U in the vertical direction (e.g., the Z-axis direction). The second connection structure 420 may intersect the support structure 300 on the support structure 300, and at least a portion of the upper surface of the support structure 300 may be exposed from the second connection structure 420.

The second connection structure 420 may be in contact with each of the first semiconductor chip 210 disposed at the top of the plurality of semiconductor chips 200 and the second semiconductor chip 220 disposed on a level adjacent thereto. The second connection structure 420 may include horizontal portions 420H in contact with the upper surfaces of the first semiconductor chip 210 and the second semiconductor chip 220, respectively, and extension portions 420C connecting the horizontal portions 420H. The horizontal portions 420H may extend parallel to the upper surfaces of the plurality of semiconductor chips 200, and the extension portion 420C may extend along the side surface of the support structure 300. A structure in which the extension portion 420C is disposed may be determined depending on the shape of the support structure 300 according to an example embodiment. The second connection structure 420 may be in the form of a bar disposed on the upper surfaces of the plurality of semiconductor chips 200, corresponding to steps on which the plurality of semiconductor chips 200 are disposed. The second connection structure 420 may be in the shape of a bar with rounded ends. The second connection structure 420 may be referred to as a conductive line. The second connection structure 420 (e.g., a conductive line) and the first connection structure 410 (e.g., a bonding wire) may extend in a same direction (e.g., in parallel).

The second connection structure 420 may include a conductive material. According to an example embodiment, the second connection structure 420 may include the same material as the first connection structure 410, but is not limited thereto. Because the semiconductor package according to some example embodiments of the present inventive concepts adopt the second connection structure 420 electrically connecting the top semiconductor chip among the plurality of semiconductor chips 200 to the semiconductor chip on the lower level, a space inevitably occupied by bonding wires of the related art extending to a level higher than the upper surface of the top semiconductor chip may be reduced, thereby achieving a lighter, thinner, shorter, and smaller semiconductor package.

The encapsulant 500 may encapsulate at least a portion of each of the plurality of semiconductor chips 200, the support structure 300, the first connection structure 410, and the second connection structure 420 on the upper surface of the package substrate 110, respectively. The encapsulant 500 may include, for example, a thermosetting resin, such as an epoxy resin, a thermoplastic resin, such as polyimide, or prepreg obtained by impregnating these resins with an inorganic filler, ABF, FR-4, BT, epoxy molding compound (EMC).

External connection conductors 600 may be disposed on the lower surface of the package substrate 110 and may be electrically connected to the interconnection circuit 112 and the lower pads 113L. The external connection conductors 600 may physically and/or electrically connect the semiconductor package 100A to an external device. The external connection conductors 600 may include a conductive material and may have a ball, pin, or lead shape. For example, the external connection conductors 600 may be solder balls.

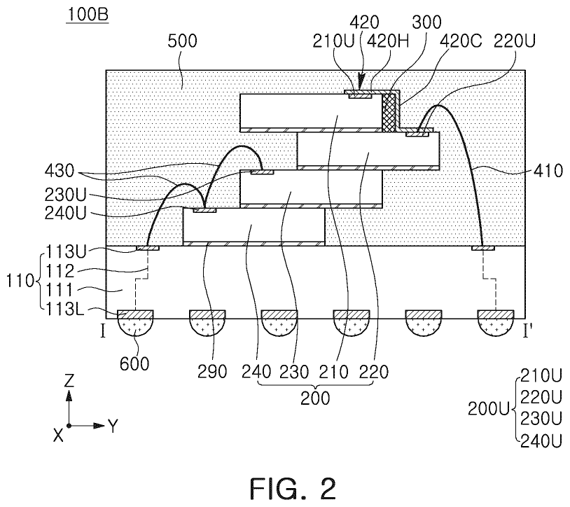

FIG. 2 is a cross-sectional view of a semiconductor package 100B according to an example embodiment of the present inventive concepts.

Referring to FIG. 2, the semiconductor package 100B of an example embodiment may have the same or similar features as those described above with reference to FIGS. 1A and 1B, except that the support structure 300 has a rectangular cross-sectional shape. The support structure 300 may be disposed on the second semiconductor chip 220, and the side surface of the support structure 300 may be perpendicular to the upper surface of the second semiconductor chip 220. The second connection structure 420 disposed on the support structure 300 may be determined depending on the shape of the support structure 300, and the extension portion 420C may be perpendicular to the upper surface of the second semiconductor chip 220. The shape of the support structure 300 is not limited to that illustrated in FIG. 2, may cover at least a portion of the side surface of the first semiconductor chip 210, and have various shapes.

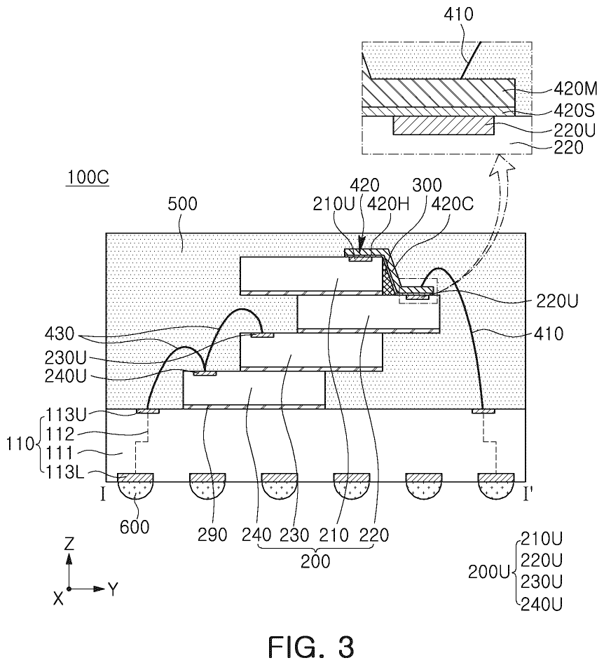

FIG. 3 is a cross-sectional view of a semiconductor package 100C according to an example embodiment of the present inventive concepts.

Referring to FIG. 3, in the semiconductor package 100C of an example embodiment, the second connection structure 420 may include a barrier layer 420S and a conductive layer 420M and may have the same or similar features as those described above with reference to FIGS. 1A to 2, except that the first connection structure 410 contacts an upper surface of the second connection structure 420. The barrier layer 420S may be formed on at least a portion of the connection pads 210U of the first semiconductor chip 210 and the connection pads 220U of the second semiconductor chip 220. The barrier layer 420S may correspond to a portion of a seed layer according to a plating process. The conductive layer 420M may be formed on the barrier layer 420S. A thickness of the conductive layer 420S may be greater than a thickness of the barrier layer 420S. The first connection structure 410 may contact the upper surface of the second connection structure 420 (e.g., the upper surface of the conductive layer 420M). In other words, the first connection structure 410 does not contact the first semiconductor chip 210, but does contact the conductive layer 420M of the second connection structure 420.

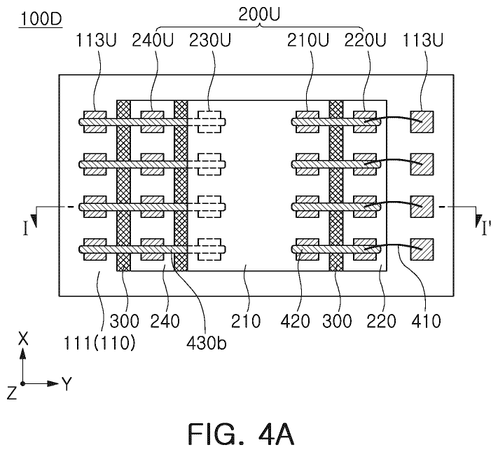

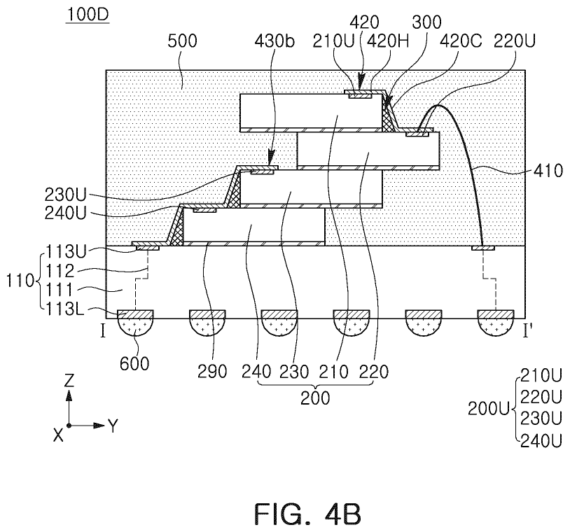

FIG. 4A is a plan view of a semiconductor package according to an example embodiment of the present inventive concepts, and FIG. 4B is a cross-sectional view of the semiconductor package of FIG. 4A taken along line I-I′.

Referring to FIGS. 4A and 4B, the semiconductor package 100D of an example embodiment may have the same or similar features as those described above with reference to FIGS. 1A to 3, except that the third connection structure 430b is in the form of a conductive line. The third connection structure 430b may have the form of a conductive line, connect the connection pads 230U and 240U of the semiconductor chips 230 and 240 among the plurality of semiconductor chips to the upper pads 113U of the package substrate 110, and may extend in the second direction (e.g., the Y-axis direction). The third connection structure 430b may extend along the steps between the plurality of semiconductor chips 200 stacked in the vertical direction and may be connected to each other.

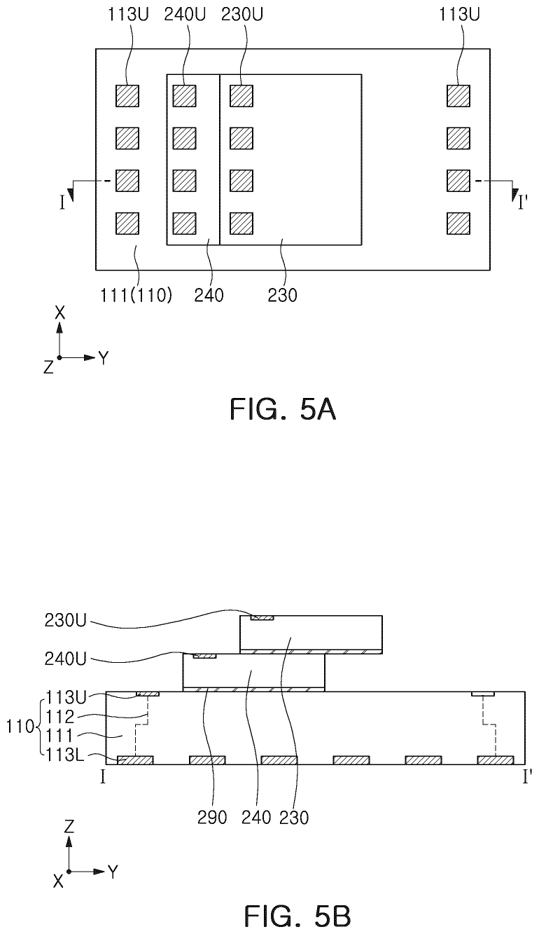

FIGS. 5A to 9B are plan views and cross-sectional views schematically illustrating a manufacturing process of a semiconductor package according to an example embodiment of the present inventive concepts.

FIGS. 5A, 6A, 7A, 8A, and 9A are plan views schematically illustrating the manufacturing process of the semiconductor package 100A according to an example embodiment of the present inventive concepts, and FIGS. 5B, 6B, 7B, and FIG. 8B and 9B are cross-sectional views taken along line I-I,′ respectively.

Referring to FIGS. 5A and 5B, a plurality of semiconductor chips 200 may be disposed on the package substrate 110. The adhesive film 290 may be attached to the lower surface of each of the plurality of semiconductor chips 200. A plurality of semiconductor chips 200 may be adhered to each other using the adhesive film 290, and the bottommost semiconductor chip 240 may be adhered to the package substrate 110 using the adhesive film 290. The package substrate 110 may include the insulating layer 111, the interconnection circuit 112 disposed in the insulating layer 111, and the upper pads 113U and the lower pads 113L electrically connected through the interconnection circuit 112. The upper pads 113U and the lower pads 113L may be exposed from the insulating layer 111. The plurality of semiconductor chips 230 and 240 may be arranged to be spaced apart from the upper pads 113U. The plurality of semiconductor chips 230 and 240 may be stacked in offset alignment or in a zigzag form so that the side surfaces thereof do not match each other.

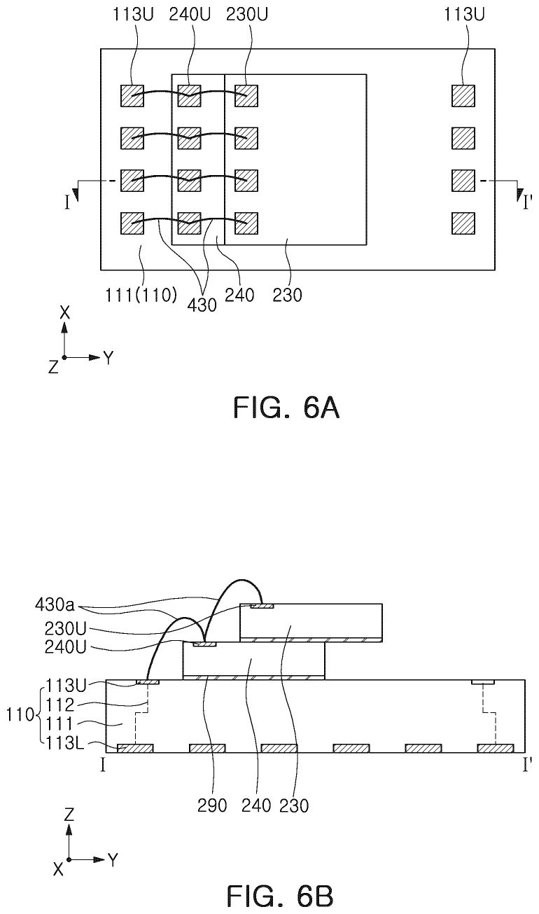

Referring to FIGS. 6A and 6B, the third connection structure 430a may be formed to electrically connect the package substrate 110 to the bottommost semiconductor chip 240 and the plurality of semiconductor chips 230 and 240 to each other. For example, the third connection structure 430a may connect the upper pad 113U of the package substrate 110 to the connection pad 240U of the bottommost semiconductor chip 240 and may connect the connection pads 230U and 240U of the plurality of semiconductor chips 230 and 240. The third connection structure 430a may include a conductive material. The third connection structure 430a may have the shape of a wire as illustrated, but is not limited thereto, and may have the shape of a conductive line according to an example embodiment (see ‘100D’ in FIGS. 4A and 4B).

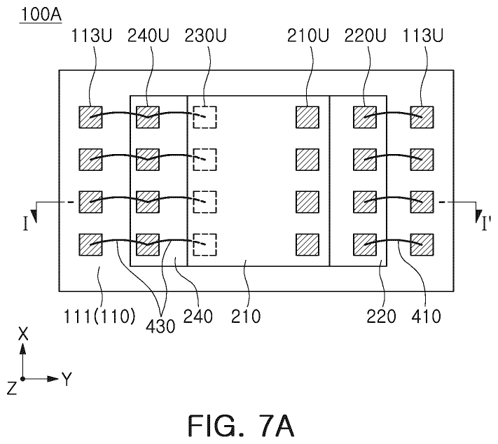

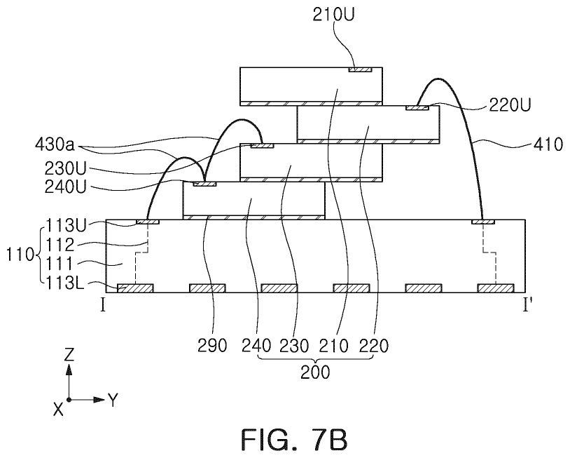

Referring to FIGS. 7A and 7B, the second semiconductor chip 220 and the first semiconductor chip 210 may be sequentially stacked, and the first connection structure 410 may be formed. The second semiconductor chip 220 and the first semiconductor chip 210 may be offset aligned on the plurality of semiconductor chips 230 and 240 stacked in the previous process, and the connection pads 220U on the second semiconductor chip 220 may be electrically connected to the upper pad 113U of the package substrate 110 through the first connection structure 410.

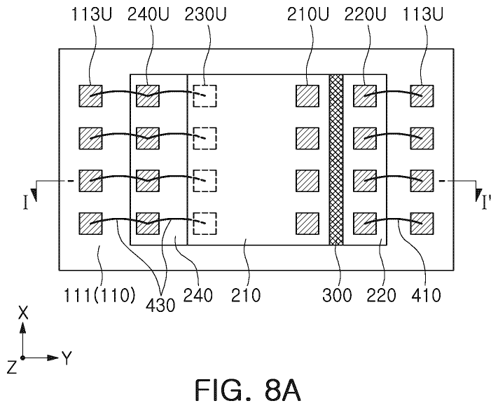

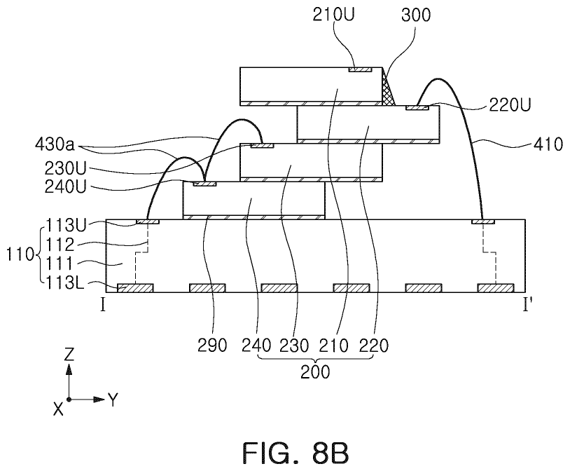

Referring to FIGS. 8A and 8B, the support structure 300 may be disposed on one side of the upper surface of the second semiconductor chip 220. The support structure 300 may be formed by curing a known insulating resin, such as an epoxy resin. The support structure 300 may be disposed to contact at least a portion of the side surface of the first semiconductor chip 210. The height of the support structure 300 may be the same as the height of the first semiconductor chip 210, as illustrated, but is not limited thereto, and may be greater than or smaller than the height of the first semiconductor chip 210 according to some example embodiments. The support structure 300 may be disposed to be spaced apart from the connection pads 220U so that the connection pads 220U on the second semiconductor chip 220 are exposed.

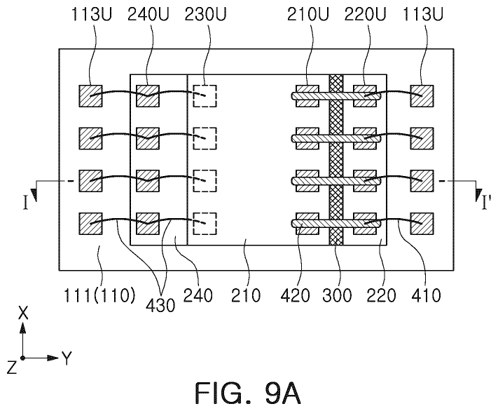

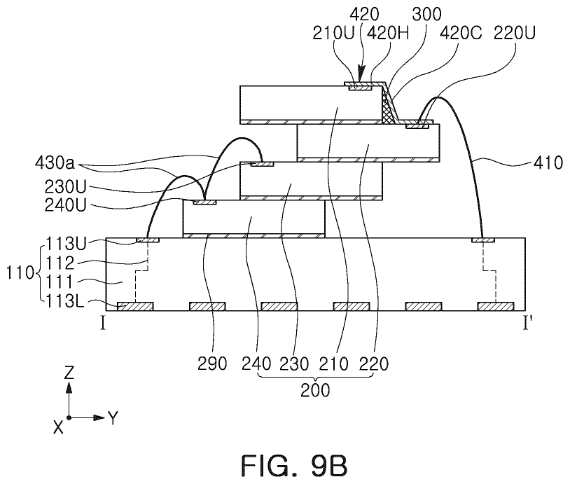

Referring to FIGS. 9A and 9B, the second connection structure 420 connecting the connection pads 210U and 220U and extending in the second direction may be formed. The second connection structure 420 may be formed through a plating process or a process of dispensing a metal material. The second connection structure 420 may be formed on the first semiconductor chip 210 and the second semiconductor chip 220 on a level adjacent to the first semiconductor chip 210. The second connection structure 420 may be formed by dispensing a metal material along a step between the plurality of semiconductor chips 200. Both ends of the second connection structure 420 may extend to pass through the connection pads 210U on the first semiconductor chip 210 and the connection pads 220U on the second semiconductor chip 220, but the present inventive concepts are not limited thereto. In some example embodiments, both ends of the second connection structure 420 may overlap the connection pads 210U and 220U in the vertical direction. Both ends of the second connection structure 420 may be partially rounded during the dispensing process. In the case of forming the second connection structure 420 through a plating process (see ‘100C’ in FIG. 3), the second connection structure 420 may include the barrier layer 420S and the conductive layer 420M disposed on the barrier layer 420S. The barrier layer 420S may correspond to a portion of the seed layer in the plating process.

Referring to FIGS. 1A and 1B, in a subsequent process, the encapsulant 500 may be formed on the upper surface of the package substrate 110, and the external connection conductors 600 may be formed on the lower pads 113L on the lower surface of the package substrate 110.

The encapsulant 500 encapsulating at least a portion of each of the package substrate 110 and the plurality of semiconductor chips 200 may be formed. The encapsulant 500 may be formed by applying an encapsulating material on the package substrate 110 and curing the encapsulating material. The encapsulant 500 may cover a portion of each of the first connection structure 410 and the second connection structure 420. The encapsulant 500 may cover a portion of each of the third connection structures 430a, and the encapsulant 500 may cover a side surface of each of the plurality of semiconductor chips 200 and at least a portion of the adhesive film 290.

The external connection conductors 600 may be attached to the lower pads 113L, and the semiconductor package 100A according to an example embodiment of the present inventive concepts may be formed.

According to some example embodiments of the present inventive concepts, thinner semiconductor packages may be provided by introducing the conductive line connecting the uppermost chip and the adjacent chip.

While some example embodiments have been illustrated and described above, it will be apparent to those skilled in the art that modifications and variations could be made without departing from the scope of the present inventive concepts as defined by the appended claims.

What is claimed is:

1. A semiconductor package comprising:
a package substrate including an insulating layer, an interconnection circuit, upper pads, and lower pads, the interconnection circuit being in the insulating layer and connecting the upper pads and the lower pads;
a plurality of semiconductor chips stacked in a direction perpendicular to an upper surface of the package substrate, each of the plurality of semiconductor chips including connection pads spaced apart from each other in a first direction on one side of an upper surface thereof;
a support structure contacting at least a portion of a side surface of a first semiconductor chip and at least a portion of an upper surface of a second semiconductor chip, the first semiconductor chip being an uppermost one among the plurality of semiconductor chips, the second semiconductor chip being one among the plurality of semiconductor chips below the first semiconductor chip;
a first connection structure extending in a second direction intersecting the first direction, the first connection structure connecting the upper pads of the package substrate to the connection pads of the second semiconductor chip, the connection pads of the second semiconductor chip being adjacent to the upper pads of the semiconductor package in the second direction;
a second connection structure extending along the upper surface of the first semiconductor chip, a side surface of the support structure, and the upper surface of the second semiconductor chip, and the second connection structure connecting the connection pads of the first semiconductor chip to the connection pads of the second semiconductor chip, the connection pads of the second semiconductor chip being adjacent to the connection pads of the first semiconductor chip in the second direction; and
an encapsulant covering at least a portion of each of the plurality of semiconductor chips, the first connection structure, and the second connection structure,
wherein the support structure has an inclined side surface having a width increasing toward the upper surface of the second semiconductor chip.

2. The semiconductor package of claim 1, wherein the first connection structure and the second connection structure include a same material.

3. The semiconductor package of claim 2, wherein the first connection structure and the second connection structure are formed of gold (Au), silver (Ag), copper (Cu), or alloys thereof.

4. The semiconductor package of claim 1, wherein an uppermost end of the second connection structure is at a higher level than an uppermost end of the first connection structure.

5. The semiconductor package of claim 1, wherein the second connection structure includes a barrier layer and a conductive layer on the barrier layer, the barrier layer being in contact with the connection pads.

6. The semiconductor package of claim 1, wherein side surfaces of the plurality of semiconductor chips are offset aligned not to match each other.

7. The semiconductor package of claim 1, wherein the second connection structure is in contact with the first connection structure.

8. The semiconductor package of claim 1, wherein the support structure extends in the first direction.

9. The semiconductor package of claim 1, further comprising:
adhesive films below each of the plurality of semiconductor chips.

10. The semiconductor package of claim 1, wherein the connection pads on the upper surface of the second semiconductor chip are in contact with both the first connection structure and the second connection structure.

11. The semiconductor package of claim 1, wherein the second connection structure extends in the second direction.

12. The semiconductor package of claim 1, wherein, in plan view, the support structure is between the connection pads of the upper surface of the first semiconductor chip and the connection pads of the upper surface of the second semiconductor chip.

13. The semiconductor package of claim 1, wherein the first connection structure does not contact the first semiconductor chip.

14. The semiconductor package of claim 1, further comprising:
external connection conductors on a lower surface of the package substrate.

15. A semiconductor package comprising:
a package substrate including upper pads and lower pads;
a plurality of semiconductor chips sequentially stacked on the package substrate, each of the plurality of semiconductor chips including connection pads arranged on a first side surface portion thereof in a first direction;
a support structure being adjacent to a first side surface of at least one semiconductor chip among the plurality of semiconductor chips;
a first connection structure electrically connecting one of the upper pads to one of the connection pads; and
a second connection structure electrically connecting the connection pads of at least one pair of vertically adjacent semiconductor chips, among the plurality of semiconductor chips, with each other,
wherein the second connection structure includes a barrier layer and a conductive layer on the barrier layer, the barrier layer being in contact with a corresponding pair of the connection pads of the at least one pair of vertically adjacent semiconductor chips, and
the first connection structure is in contact with an upper surface of the conductive layer.

16. The semiconductor package of claim 15, wherein the second connection structure includes a plurality of horizontal portions and an extension portion, each of the plurality of horizontal portions being in contact with an upper surface of a corresponding one of the at least one pair of vertically adjacent semiconductor chips, respectively, the extension portion contacting the support structure and connecting the plurality of horizontal portions.

17. The semiconductor package of claim 16, wherein the extension portion extends in a direction perpendicular to the upper surface of the corresponding one of the at least one pair of semiconductor chips.

18. A semiconductor package comprising:
a package substrate including upper pads aligned in a first direction;
a plurality of semiconductor chips stacked on the package substrate in a vertical direction, the plurality of semiconductor chips including connection pads aligned in the first direction on one side of an upper surface thereof;
a support structure being between the connection pads of each of at least one pair of adjacent semiconductor chips among the plurality of semiconductor chips, in plan view;
a bonding wire electrically connecting one of the upper pads to a corresponding one of the connection pads; and
a plurality of conductive lines electrically connecting the connection pads of the at least one pair of adjacent semiconductor chips with each other,
wherein each of the plurality of conductive lines intersects the support structure in plan view.

19. The semiconductor package of claim 18, wherein at least one of the plurality of conductive lines surrounds at least a portion of the bonding wire.

20. The semiconductor package of claim 18, wherein each of the plurality of conductive lines and the bonding wire extend in parallel.
